(19) United States
(12) Patent Application Publication
(10) Pub. No.: US 2019/0091833 A1
(43) Pub. Date: Mar. 28, 2019

(54) CHEMICAL MECHANICAL POLISHING METHOD AND METHOD FOR FABRICATING SEMICONDUCTOR DEVICE

(71) Applicant: SAMSUNG ELECTRONICS CO., LTD., Suwon-si (KR)

(72) Inventors: Sol HAN, Seoul (KR); Yung Jun KIM, Daegu (KR); Ho Young KIM, Gunpo-si (KR); Doo Sik MOON, Suwon-si (KR); Sung Oh PARK, Suwon-si (KR); Young Seok JANG, Suwon-si (KR); Sun Gyu PARK, Seoul (KR); Kyu Min OH, Suwon-si (KR); Joo Han LEE, Seongnam-si (KR)

(73) Assignee: EHWA DIAMOND IND. CO., LTD., Osan-si (KR)

(21) Appl. No.: 15/957,012

(22) Filed: Apr. 19, 2018

(30) Foreign Application Priority Data
Sep. 28, 2017 (KR) 10-2017-0126440

(51) Int. Cl. B24B 53/017; B24B 37/005; H01L 21/306

(52) U.S. Cl. CPC B24B 53/017; H01L 21/30625; B24B 37/005

(57) ABSTRACT

A chemical mechanical polishing method includes providing a pad conditioner, such that the pad conditioner includes a base and a plurality of tips protruding from a surface of the base, adjusting a surface roughness of an upper surface of each tip of the plurality of tips, and adjusting a polishing rate of chemical mechanical polishing using the adjusted surface roughness of the upper surfaces of the plurality of tips.

### CROSS-REFERENCE TO RELATED APPLICATION

Korean Patent Application No. 10-2017-0126440 filed on Sep. 28, 2017, in the Korean Intellectual Property Office, and entitled: “Chemical Mechanical Polishing Method And Method For Fabricating Semiconductor Device,” is incorporated by reference herein in its entirety

### BACKGROUND

### 1. Field

The present disclosure relates to a chemical mechanical polishing method and a method for fabricating a semiconductor device, and more particularly, to a chemical mechanical polishing method using a pad conditioner and a method for fabricating a semiconductor device.

### 2. Description of the Related Art

In a planarization process using a chemical mechanical polishing (CMP) apparatus, the profile of a polishing pad has a great influence on the characteristics of the flatness of the wafer surface to be polished. Therefore, in order to smoothly perform a wafer planarization process by using the chemical mechanical polishing apparatus, the profile of the polishing pad must be maintained in a state suitable for the process.

### SUMMARY

According to aspects of the present disclosure, there is provided a chemical mechanical polishing method that includes providing a pad conditioner, such that the pad conditioner includes a base and a plurality of tips protruding from a surface of the base, adjusting a surface roughness of an upper surface of each tip of the plurality of tips, and adjusting a polishing rate of chemical mechanical polishing using the adjusted surface.

According to aspects of the present disclosure, there is also provided a chemical mechanical polishing method that includes providing a pad conditioner including a base and a plurality of tips protruding from a surface of the base, determining an optimal surface roughness of an upper surface of each of the tips, adjusting a surface roughness of the upper surface of each of the tips such that the upper surface of each of the tips has the optimal surface roughness, performing conditioning on a polishing pad using the pad conditioner, and polishing a wafer using the polishing pad.

According to aspects of the present disclosure, there is also provided a method for fabricating a semiconductor device that includes providing a wafer, and polishing the wafer using a chemical mechanical polishing method, wherein the chemical mechanical polishing method includes providing a pad conditioner including a base and a plurality of tips protruding from a surface of the base, adjusting a surface roughness of an upper surface of each of the tips, and adjusting a polishing rate of chemical mechanical polishing using the adjusted surface roughness of the upper surface of the tip.

### BRIEF DESCRIPTION OF THE DRAWINGS

Features will become apparent to those of skill in the art by describing in detail exemplary embodiments with reference to the attached drawings, in which:

FIG. 1 illustrates a flowchart of a chemical mechanical polishing method according to some embodiments of the present disclosure.

FIG. 2 illustrates a schematic perspective view of a pad conditioner according to some embodiments of the present disclosure.

FIGS. 3a-3d illustrate enlarged views of a portion P of FIG. 2.

FIG. 4 illustrates a cross-sectional view taken along line X-X′ of FIG. 2.

FIG. 5 illustrates an enlarged view of a portion Q of FIG. 4.

FIG. 6 illustrates a schematic diagram of the provision of a pad conditioner according to some embodiments of the present disclosure.

FIGS. 7 and 8 illustrate schematic diagrams explaining the adjustment of the surface roughness of the upper surface of the tip according to some embodiments of the present disclosure.

FIG. 9 illustrates a flowchart of a chemical mechanical polishing method according to some embodiments of the present disclosure.

FIG. 10 illustrates a schematic diagram of a conditioning process according to some embodiments of the present disclosure.

FIG. 11 illustrates a schematic diagram of polishing a wafer according to some embodiments of the present disclosure.

FIG. 12 illustrates a flowchart of a chemical mechanical polishing method according to some embodiments of the present disclosure.

FIG. 13 illustrates a flowchart of the determination of an optimal surface roughness according to some embodiments of the present disclosure.

FIG. 14 illustrates a diagram explaining the provision of a test pad conditioner according to some embodiments of the present disclosure.

FIG. 15 illustrates a graph explaining the determination of the optimal surface roughness using the measured polishing rate in some embodiments of the present disclosure.

FIG. 16 illustrates a graph explaining the determination of the optimal surface roughness using the measured polishing rate in some embodiments of the present disclosure.

FIG. 17 illustrates a flowchart explaining a method for fabricating a semiconductor device according to some embodiments of the present disclosure.

### DETAILED DESCRIPTION

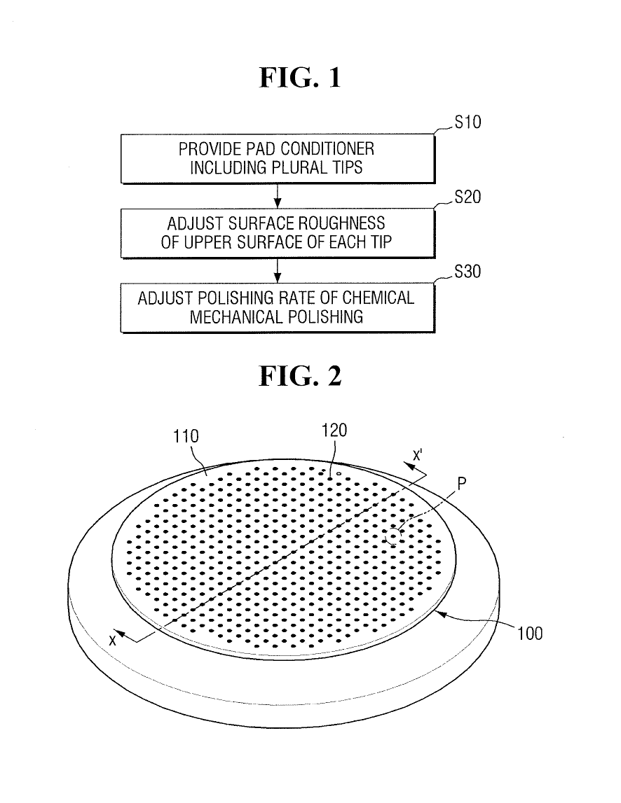

Hereinafter, a chemical mechanical polishing method according to some embodiments of the present disclosure will be described with reference to FIGS. 1 to 11.

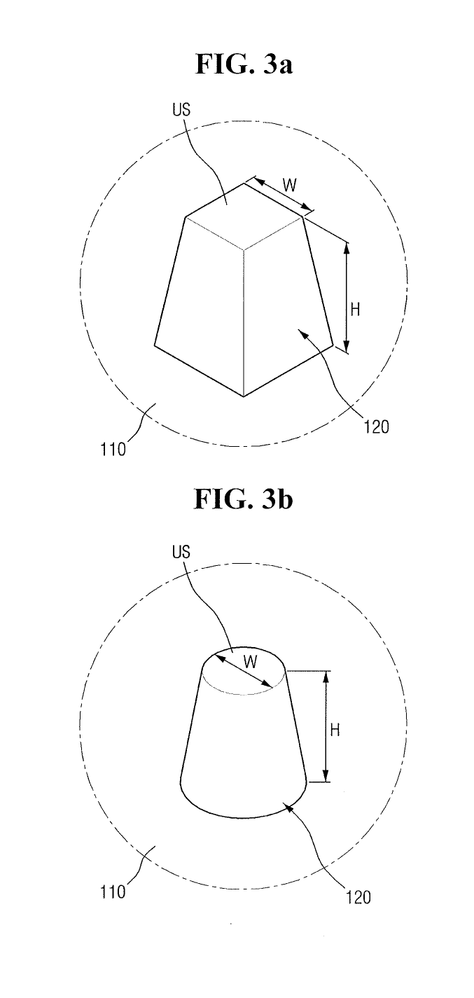

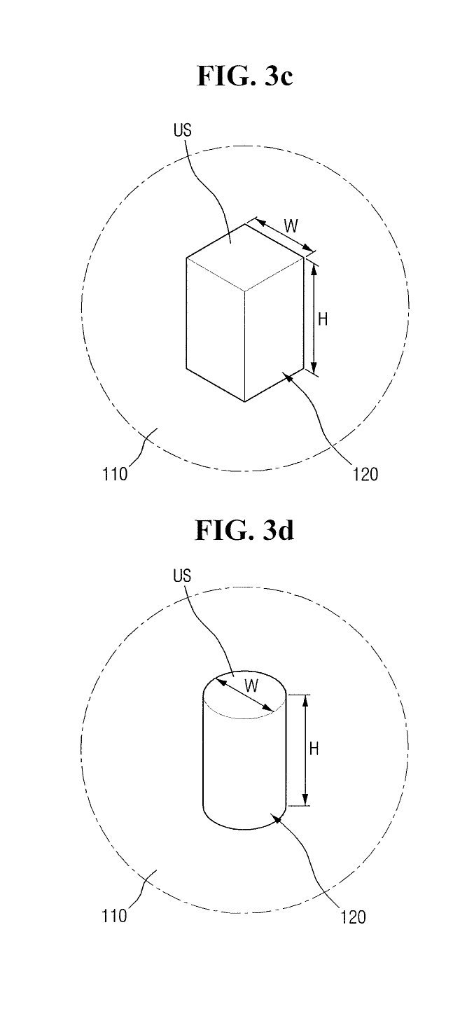

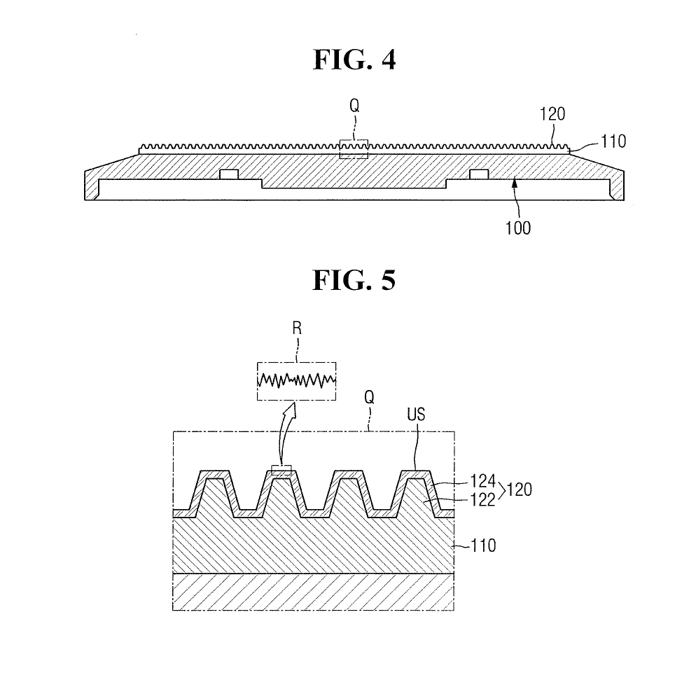

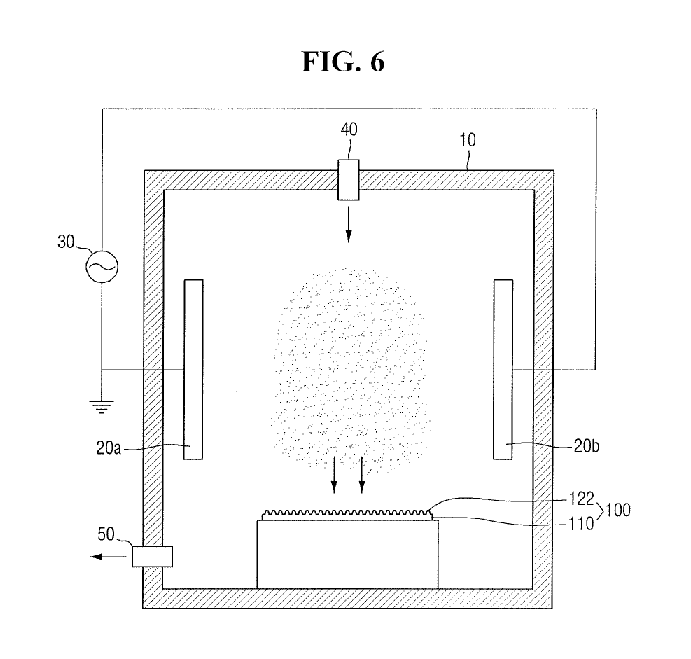

FIG. 1 is a flowchart explaining a chemical mechanical polishing method according to some embodiments of the present disclosure. FIG. 2 is a schematic perspective view illustrating a pad conditioner according to some embodiments of the present disclosure. FIGS. 3a, 3b, 3c and 3d are enlarged views of a portion P of FIG. 2. FIG. 4 is a cross-sectional view taken along line X-X′ of FIG. 2. FIG. 5 is an enlarged view of a portion Q of FIG. 4. FIG. 6 is a schematic diagram illustrating the provision of a pad conditioner according to some embodiments of the present disclosure.

Referring to FIGS. 1 to 5, a pad conditioner 100 including a plurality of tips 120 is provided (S10). As illustrated in FIG. 2, the pad conditioner 100 may include a base 110 and a plurality of tips 120 protruding from the surface of the base 110.

The base 110 may have a flat shape when viewed from above. For example, the base 110 may have a disc shape.

The base 110 may include a material having high strength and high hardness. For example, the base 110 may include at least one of ferroalloy, cemented carbide, and ceramic. For example, the base 110 may include cemented carbide based on tungsten carbide (WC), e.g., tungsten carbide-cobalt (WC—Co), tungsten carbide-titanium carbide-cobalt (WC—TiC—Co) and tungsten carbide-titanium carbide-tantalum carbide-cobalt (WC—TiC—TaC—Co). For example, the base 110 may include cemented carbide based on titanium carbide nitride (TiCN), boron carbide (B₄C) and titanium boride (TiB₂). For example, the base 110 may include a ceramic-based material containing at least one of, e.g., silicon nitride (Si₃N₄), silicon (Si), aluminum oxide (Al₂O₃), aluminum nitride (AlN), titanium oxide (TiO₂), zirconium oxide (ZrOₓ), silicon oxide (SiO₂), silicon carbide (SiC), silicon oxynitride (SiOₓN_{y}), tungsten nitride (WNₓ), tungsten oxide (WOₓ), diamond like coating (DLC), boron nitride (BN) and chromium oxide (Cr₂O₃).

The plurality of tips 120 may be formed on the base 110. The plurality of tips 120 may be formed to protrude from the surface of the base 110. For example, as illustrated in FIG. 4, the plurality of tips 120 may be formed to protrude upward from an upper surface of the base 110.

The plurality of tips 120 may be spaced apart from each other on the base 110. Further, the plurality of tips 120 may be repeatedly arranged on the base 110. For example, the plurality of tips 120 may be arranged on the base 110 in the form of a mesh or a lattice, e.g., the plurality of tips 120 may be arranged on the base 110 equidistantly from each other along two different directions in a matrix pattern.

Each tip 120 protrudes from the surface of the base 110 and may include various shapes. The different shapes of the tips will be discussed in more detail below with reference to FIGS. 3a-3d.

For example, as shown in FIG. 3a, each tip 120 may have a truncated pyramid shape. Thus, each tip 120 may have a polygonal upper surface US. Although it is illustrated in FIG. 3a that the upper surface US of the tip 120 has a square shape in top view, the upper surface US of the tip 120 may have various polygonal shapes in top view, e.g., a rectangle, a pentagon, and the like. Further, the sidewall of the tip 120 may be inclined, e.g., a width of the sidewall of the tip 120 may be gradually reduced as a distance from the base 110 increases. For example, the cross-sectional area of a lower portion of the tip 120 in contact with the base 110 in a top view may be greater than the cross-sectional area of the upper surface US of the tip 120 in a top view.

In another example, as shown in FIG. 3b, each tip 120 may have a truncated cone shape. Thus, each tip 120 may have a circular upper surface US. Although it is illustrated in FIG. 3b that the upper surface of the tip 120 has a circular shape, the upper surface of the tip 120 may have an elliptical shape. Further, the sidewall of the tip 120 may be inclined. For example, the cross-sectional area of the lower portion of the tip 120 in contact with the base 110 in a top view may be greater than the cross-sectional area of the upper surface US of the tip 120 in a top view.

In yet another example, as shown in FIG. 3c, each tip 120 may have a prism shape. Thus, each tip 120 may have a polygonal upper surface US, while the, e.g., entire, sidewall of the tip 120 may be substantially perpendicular to the upper surface of the base 110. The cross-sectional area of the lower portion of the tip 120 in contact with the base 110 in a top view may be substantially equal to the cross-sectional area of the upper surface US of the tip 120 in a top view.

In still another example, as shown in FIG. 3d, each tip 120 may have a cylindrical shape. Thus, each tip 120 may have a circular upper surface US, while the, e.g., entire, sidewall of the tip 120 may be substantially perpendicular to the upper surface of the base 110. The cross-sectional area of the lower portion of the tip 120 in contact with the base 110 in a top view may be substantially equal to the cross-sectional area of the upper surface US of the tip 120 in a top view.

Referring to FIGS. 3a-3d, a width W of the upper surface US of each tip 120 may range from about 10 μm to about 100 μm. Here, the width W of the upper surface US of the tip 120 means a diameter or a length of one side of the upper surface US. For example, in FIGS. 3a and 3c, the length of one side of the upper surface US of the tip 120 may range from about 10 μm to about 100 μm, e.g., a length of each side may be from about 10 μm to about 100 μm when the upper surface US has a rectangular or a pentagonal cross section in top view. For example, in FIGS. 3b and 3d, the diameter of the upper surface US of the tip 120 may range from about 10 μm to about 100 μm e.g., a length of each of the diameters may be from about 10 μm to about 100 μm when the upper surface US has an elliptical cross section in top view.

A height H of each tip 120 may range from about 30 μm to about 250 μm. Here, the height H of the tip 120 means a distance from the upper surface of the base 110 to the upper surface US of the tip 120 along a direction normal to the upper surface of the base 110. For example, in FIGS. 3a to 3d, the distance from the upper surface of the base 110 to the upper surface US of the tip 120 may range from about 30 μm to about 250 μm.

As shown in FIG. 5, each tip 120 may include a protrusion 122 and a cutting portion 124. For example, each tip 120 illustrated in FIGS. 3a-3d reflects a schematic representation of a protrusion 122 with a cutting portion 124 thereon, e.g., the cutting portion 124 may be conformal on the protrusion to trace the profile of the protrusion 122, so the height H represents a total height of the protrusion 122 with the cutting portion 124, and the width W represents a total width of the upper surface US of the protrusion 122 with the cutting portion 124.

The protrusion 122 of each tip 120 may be formed to protrude from the surface of the base 110. That is, a plurality of protrusions 122 may be formed on the base 110.

The plurality of protrusions 122 may be spaced apart from each other on the base 110. Also, the plurality of protrusions 122 may be repeatedly arranged on the base 110. For example, the plurality of protrusions 122 may be arranged on the base 110 in the form of a mesh or a lattice. Although it is illustrated in FIG. 5 that the plurality of protrusions 122 have the same height, the plurality of protrusions 122 may have different heights.

The protrusion 122 of the tip 120 may be formed, for example, by machining the base 110. For example, the plurality of protrusions 122 may be formed by etching a portion of the base 110, e.g., by mechanical processing, laser processing, or etching. In this case, the protrusion 122 of the tip 120 may include the same material as the base 110.

The cutting portion 124 of the tip 120 may be formed on the base 110 and the protrusion 122. For example, the cutting portion 124 may be formed along the profile of the surface of the base 110 and the surface of the protrusion 122, e.g., the cutting portion 124 may be formed conformally on the surface of the protrusion 122 and on the surface of the base 110 to trace the profile of the protrusion 122 on the base 110. Accordingly, the cutting portion 124 may cover the upper surface of the base 110, the sidewalls of the protrusions 122, and the upper surfaces of the protrusions 122.

The cutting portion 124 may include, e.g., chemical vapor deposition (CVD) diamond. For example, the cutting portion 124 may be formed by performing a diamond coating process on the base 110 and the protrusion 122 using a diamond coating apparatus. An example of a diamond coating apparatus is illustrated in FIG. 6.

Referring to FIG. 6, a diamond coating apparatus according to some embodiments may include a chamber 10, a first electrode 20a, a second electrode 20b, a power source 30, a gas supply pipe 40, and a gas exhaust pipe 50.

The chamber 10 may provide a space in which the diamond coating process is performed. The chamber 10 may be maintained in a vacuum or in a low pressure state, but is not limited thereto.

The gas supply pipe 40 connected to the chamber 10 may inject a gas into the chamber 10. For example, the gas supply pipe 40 may inject a gas containing carbon (e.g., CH₄) into the chamber 10. The gas exhaust pipe 50 connected to the chamber 10 may exhaust a gas generated during the diamond coating process out of the chamber 10.

The power source 30 may apply energy to the gas supplied by the gas supply pipe 40. Thus, the gas supplied by the gas supply pipe 40 may generate, e.g., a plasma. For example, the power source 30 may be connected to the first electrode 20a and the second electrode 20b to form an electric field between the first electrode 20a and the second electrode 20b. The power source 30 may be an alternating current (AC) power source, but is not limited thereto, e.g., may be a direct current (DC) power source. By the power source 30, atoms or ions containing carbon (e.g., carbon-containing radicals) may be formed in the chamber 10.

The atoms or ions containing carbon may be deposited on the base 110 and the protrusions 122 of the conditioning pad 100 to form the cutting portion 124, e.g., the atoms or ions containing carbon may be deposited on all exposed surfaces of the base 110 and protrusions 122 of the conditioning pad 100. Thus, on the base 110 and the protrusions 122, the cutting portion 124 including CVD diamond may be, e.g., continuously, formed.

The surface of the cutting portion 124 formed by the diamond coating process may have fine irregularities, e.g., unevenness. The degree of unevenness is called a surface roughness. Thus, as shown in FIG. 5, the upper surface US of each tip 120 may have a specific surface roughness defined by the irregularities in the top surface of the cutting portion 124 (enlarged portion R in dashed frame of FIG. 5).

Referring again to FIG. 1, once the pad conditioner 100 is provided, as described previously with reference to FIGS. 2-6, the surface roughness of the upper surface US of each tip 120 in the pad conditioner 100 is adjusted (S20). In other words, the surface roughness of the cutting portion 124 in each tip 120 is adjusted. Adjusting the surface roughness of the upper surface US of each tip 120 may be performed in various ways.

In some embodiments, operation S20 in FIG. 1 of adjusting the surface roughness of the upper surface US of each tip 120 may be performed at the same time, e.g., simultaneously, as operation S10 of providing the pad conditioner 100. That is, for example, adjusting the surface roughness of the upper surface US of each tip 120 may be performed during formation of the cutting portion 124 in each tip 120 of the pad conditioner 100.

For example, operation S20 of adjusting the surface roughness of the upper surface US of each tip 120 may include adjusting the process conditions of the diamond coating process. As described above with reference to FIG. 6, operation SI 0 of providing the pad conditioner 100 may include forming the cutting portion 124 on the protrusions 122 using a diamond coating process. In this case, the surface roughness of the cutting portion 124 may be adjusted during its formation on the protrusions 122 by adjusting the process conditions of the diamond coating process.

For example, the surface roughness of the cutting portion 124 may be adjusted by adjusting the stoichiometry of the gas injected by the gas supply pipe 40, the amount of energy applied by the power source 30, the deposition temperature in the chamber 10, the deposition pressure in the chamber 10, and the deposition time. Thus, the surface roughness of the upper surface US of each tip 120 may be adjusted.

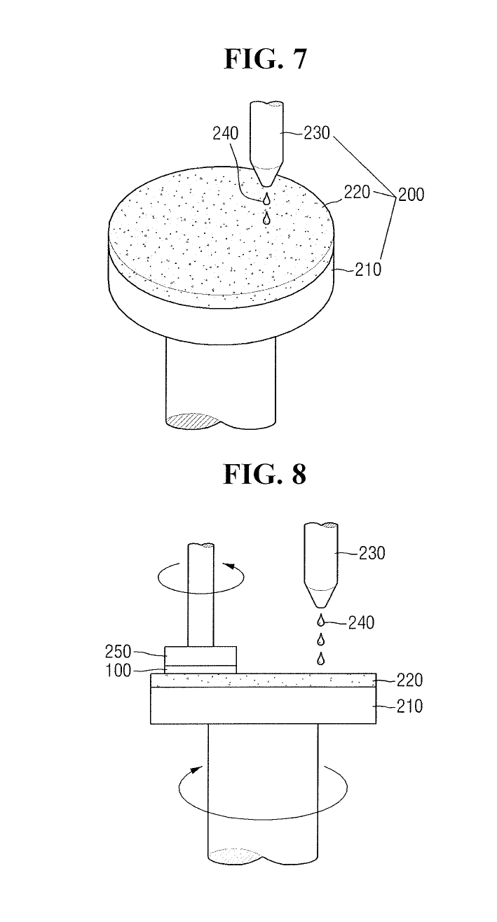

In some embodiments, operation S20 in FIG. 1 of adjusting the surface roughness of the upper surface US of each tip 120 may be performed after completion of operation S10 of providing the pad conditioner 100. That is, for example, adjusting the surface roughness of the upper surface US of each tip 120 may include reducing the surface roughness of the upper surface US of each tip 120, after formation of the cutting portion 124 on the protrusions 122 of the pad conditioner 100 is complete. This will be described in more detail with reference to FIGS. 7 and 8.

FIGS. 7 and 8 are schematic diagrams explaining the adjustment of the surface roughness of the upper surface of the tip 120 according to some embodiments of the present disclosure. For example, adjusting the surface roughness of the upper surface US of each tip 120 may include performing a dressing process on the upper surface of each tip 120. For example, the dressing process may be performed on the upper surface of each tip 120 using a pad conditioner dressing apparatus 200.

Referring to FIG. 7, the pad conditioner dressing apparatus 200 according to some embodiments may include a dressing turn table 210, a dressing pad 220, and a dressing slurry supply unit 230.

The dressing turn table 210 may provide a space in which the dressing pad 220 is mounted. Further, while the dressing is performed, the dressing turn table 210 may rotate.

The dressing pad 220 may be disposed on the dressing turn table 210. The dressing pad 220 may have, e.g., a disc shape, but is not limited thereto. The dressing pad 220 may include, e.g., a polymer having abrasion resistance. For example, the dressing pad 220 may include a pad which is impregnated with polyurethane in the nonwoven fabric. The nonwoven fabric may include polyester fibers. Alternatively, the dressing pad 220 may include, e.g., a pad on which a porous urethane layer is coated on a compressible polyurethane substrate.

The dressing slurry supply unit 230 may supply a dressing slurry 240 onto the dressing pad 220. For example, the dressing slurry supply unit 230 may supply the dressing slurry 240 onto the dressing pad 220 using a nozzle.

The dressing slurry 240 may include a chemical solution containing an abrasive. The abrasive may include a material having high mechanical hardness and high strength. For example, the abrasive may include at least one of silica, alumina, and ceria. The chemical solution may include at least one of, e.g., de-ionized water, a surfactant, a dispersing agent, and an oxidizing agent. The dressing slurry 240 may be present in a suspension state by dispersing the abrasives in a chemical solution.

Referring to FIG. 8, a dressing process may be performed on the pad conditioner 100. The pad conditioner 100 may be provided onto the upper surface of the dressing pad 220. For example, the pad conditioner 100 may be provided onto the dressing pad 220 by a pad conditioner holder 250, e.g., so the tips 120 of the pad conditioner 100 may face the dressing pad 220. The pad conditioner holder 250 may hold the pad conditioner 100, e.g., in a vacuum adsorption manner, but is not limited thereto. Although not shown, the pad conditioner holder 250 may be moved up and down using a pneumatic or hydraulic cylinder. The pad conditioner holder 250 moves up and down to apply pressure to the pad conditioner 100 such that the pad conditioner 100 can be brought into close contact with the dressing pad 220, e.g., via the tips 120.

During the dressing process, the dressing turn table 210 or the pad conditioner holder 250 may rotate. For example, the dressing turn table 210 and the pad conditioner holder 250 may rotate in opposite directions. However, the present disclosure is not limited thereto. For example, the pad conditioner holder 250 may rotate while the dressing turn table 210 is stopped, e.g., stationary. In another example, the pad conditioner holder 250 may be stopped while the dressing turn table 210 rotates.

The dressing slurry 240 may be supplied between the pad conditioner 100 and the dressing pad 220. The dressing process may be performed on the surface of the pad conditioner 100 by a mechanical action through the mechanical contact between the pad conditioner 100 and the dressing pad 220 and a chemical action using the dressing slurry 240, e.g., the mechanical and chemical actions of the dressing process may be performed between the tips 120 of the pad conditioner 100 and the dressing pad 220. Thus, the surface roughness of the upper surface US of each tip 120, i.e., of the cutting portion 124 in each tip 120 (which contacts the dressing pad 220) may be reduced.

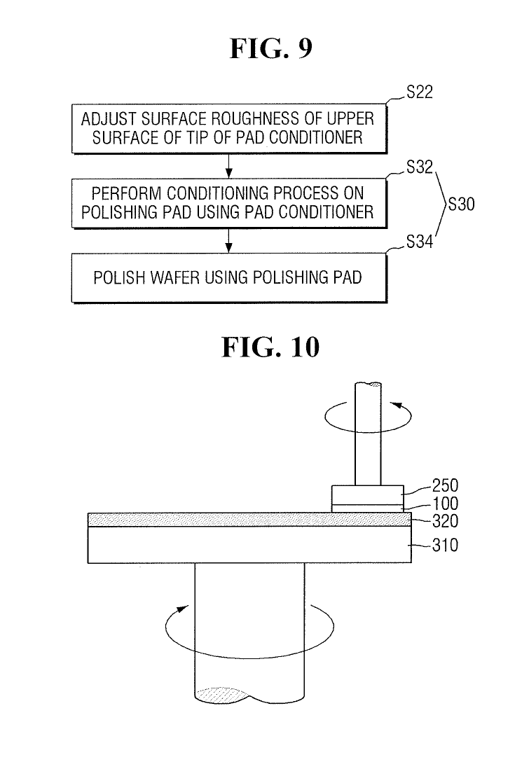

Referring again to FIG. 1, after the surface roughness of the upper surface US of each tip 120 in the pad conditioner 100 is adjusted (S20), the polishing rate of the chemical mechanical polishing is adjusted by using the surface roughness of the upper surface US of the adjusted tip 120 (S30). Hereinafter, operation S30 of adjusting the polishing rate of the chemical mechanical polishing will be described in detail with reference to FIGS. 9 to 11.

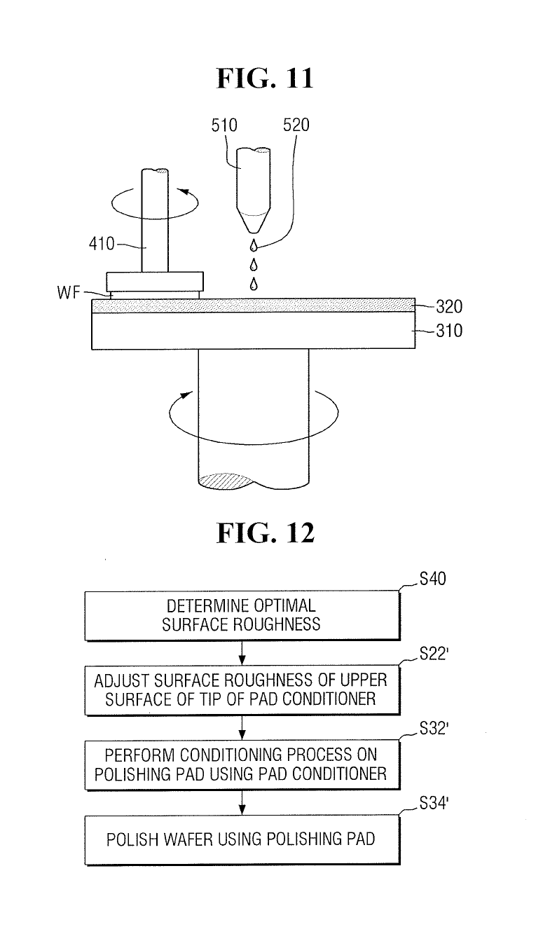

FIG. 9 is a flowchart explaining a chemical mechanical polishing method according to some embodiments of the present disclosure. FIG. 10 is a schematic diagram explaining performing a conditioning process according to some embodiments of the present disclosure. FIG. 11 is a schematic diagram explaining polishing a wafer according to some embodiments of the present disclosure.

Referring to FIG. 9, the surface roughness of the upper surface US of the tip 120 of the pad conditioner 100 is adjusted (S22). Since operation S22 of adjusting the surface roughness of the upper surface US of the tip 120 of the pad conditioner 100 is substantially the same as operation S20 in FIG. 1 described previously, a detailed description thereof will be omitted below.

Next, referring to FIGS. 9 and 10, a conditioning process is performed on a polishing pad 320 using the pad conditioner 100 (S32). For example, the conditioning process is performed on the polishing pad 320 to adjust a surface of the polishing pad 320 in accordance with the surface roughness of the tips 120 of the pad conditioner 100.

The polishing pad 320 may be disposed on a polishing turn table 310. During the conditioning process, the polishing turn table 310 may rotate. The polishing pad 320 may have, e.g., a disc shape, but is not limited thereto. The polishing pad 320 may include, but is not limited to, e.g., a polyurethane pad.

The pad conditioner holder 250 may move up and down to apply pressure to the pad conditioner 100 such that the pad conditioner 100 can be brought into close contact with the polishing pad 320, e.g., via the tips 120. Further, during the conditioning process, the polishing turn table 310 or the pad conditioner holder 250 may rotate. For example, the polishing turn table 310 and the pad conditioner holder 250 may rotate in opposite directions. However, the present disclosure is not limited thereto. For example, the pad conditioner holder 250 may rotate while the polishing turn table 310 is stopped. In another example, the pad conditioner holder 250 may be stopped while the polishing turn table 310 rotates.

Thus, a conditioning process may be performed on the polishing pad 320. In a continuous wafer polishing process, the polishing pad 320 may be damaged by a slurry or foreign matter. As a result, the profile of the polishing pad 320 may be altered to a state different from its initial state. In order to return the altered polishing pad 320 to its initial state, a conditioning process may be performed on the polishing pad 320 using the pad conditioner 100.

The conditioning process may be performed ex-situ with the dressing process described above with reference to FIGS. 7 and 8, but is not limited thereto. In some embodiments, the conditioning process and the dressing process may be performed in-situ.

At this time, the surface roughness of the polishing pad 320 may be adjusted by using the adjusted surface roughness of the upper surface US of the tip 120. That is, the surface roughness of the polishing pad 320 may be adjusted in operation (S32) in accordance with the adjusted surface roughness of the upper surface US of the tip 120 of the pad conditioner 100 performed in operation (S22). For example, by increasing the surface roughness of the upper surface US of the tip 120 in operation (S22), the surface roughness of the polishing pad 320 conditioned by the pad conditioner 100 (via the tips 120) in operation (S32) may also be increased. In another example, by reducing the surface roughness of the upper surface US of the tip 120 in operation (S22), the surface roughness of the polishing pad 320 conditioned by the pad conditioner 100 (via the tips 120) in operation (S32) may also be reduced.

Referring to FIGS. 9 and 11, once conditioning of the polishing pad 320 in accordance with the tips 120 of the pad conditioner 100 is complete, a wafer WF may be polished using the conditioned polishing pad 320 (S34).

The wafer WF may be provided onto the upper surface of the polishing pad 320. For example, the wafer WF may be provided onto the polishing pad 320 by a polishing head 410. The polishing head 410 may hold the wafer WF, e.g., in a vacuum adsorption manner, but is not limited thereto. The polishing head 410 may be moved up and down, e.g., using a pneumatic or hydraulic cylinder. The polishing head 410 may move in the vertical direction and apply pressure to the wafer WF such that the wafer WF can be brought into close contact with the polishing pad 320.

During the polishing process of the wafer WF, the polishing turn table 310 or the polishing head 410 may rotate. For example, the polishing turn table 310 and the polishing head 410 may rotate in opposite directions. However, the present disclosure is not limited thereto. For example, the polishing head 410 may rotate while the polishing turn table 310 is stopped. In another example, the polishing head 410 may be stopped while the polishing turn table 310 rotates.

The polishing slurry supply unit 510 may supply a polishing slurry 520 between the wafer WF and the polishing pad 320. For example, the polishing slurry supply unit 510 may supply the polishing slurry 520 between the wafer WF and the polishing pad 320 using a nozzle.

The polishing slurry 520 may include a chemical solution containing an abrasive. For example, the abrasive may include at least one of silica, alumina, ceria, zirconia, titania, barium titania, germania, mangania, and magnesia. The chemical solution may include, e.g., an oxidizing agent, a hydroxylating agent, an abrasive, a surfactant, a dispersing agent, and other catalysts.

By a mechanical action through the mechanical contact between the wafer WF and the polishing pad 320 and a chemical action through the polishing slurry 520, chemical mechanical polishing may be performed on the wafer WF. At this time, the polishing rate of the chemical mechanical polishing may be adjusted by using the adjusted surface roughness of the polishing pad 320, which is adjusted in accordance with the adjusted tips 120 of the conditioning pad 100. That is, the polishing rate of the chemical mechanical polishing of the wafer WF may be adjusted by adjusting the surface roughness of the polishing pad 320, which in turn, is adjusted by adjusting the upper surface US of the tips 120 of the pad conditioner 100 (S22).

As described above, by increasing or reducing the surface roughness of the upper surface US of the tips 120 of the conditioning pad 100, the surface roughness of the polishing pad 320 may also be increased or reduced, respectively. The increased or reduced surface roughness of the polishing pad 320 may adjust the polishing rate of the chemical mechanical polishing of the wafer WF via the polishing pad 320.

In other words, the chemical mechanical polishing method according to some embodiments adjusts the surface roughness of the upper surface US of the tip 120 of the pad conditioner 100, which is used to adjust the surface roughness of the polishing pad 320. Then, the polishing pad 320 with the adjusted surface roughness (in accordance with the adjusted tips 120) is used to perform the polishing rate of the chemical mechanical polishing of the wafer WF according to the desired process, e.g., in accordance with desired process specification (e.g., type of abrasive used). Accordingly, the chemical mechanical polishing method according to some embodiments can realize an optimized and stabilized polishing rate for each process.

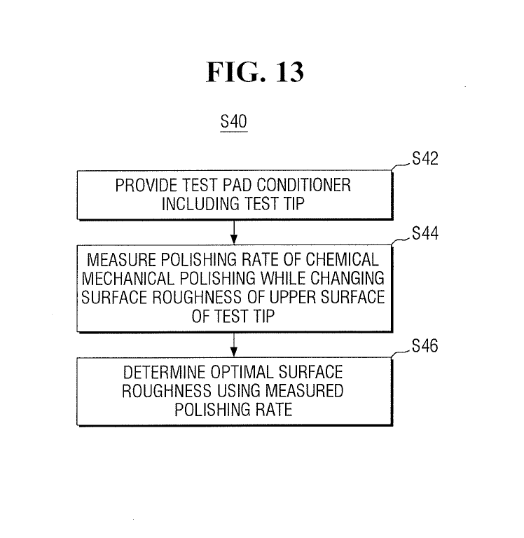

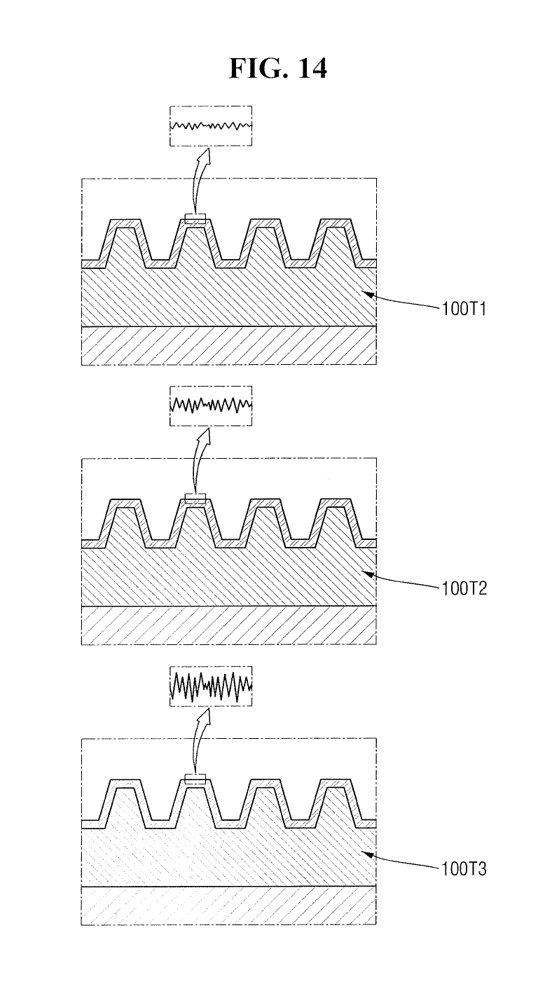

FIG. 12 is a flowchart explaining a chemical mechanical polishing method according to some embodiments of the present disclosure. FIG. 13 is a flowchart illustrating the determination of an optimal surface roughness according to some embodiments of the present disclosure. FIG. 14 is a diagram explaining the provision of a test pad conditioner according to some embodiments of the present disclosure. For convenience of description, a repeated description similar to the description with reference to FIGS. 1 to 11 will be only briefly explained or omitted.

Referring to FIG. 12, an optimal surface roughness is determined (S40). Operation S40 of determining the optimal surface roughness may be performed before adjusting the surface roughness of the upper surface US of the tip 120 of the pad conditioner 100 (S22′).

In detail, referring to FIG. 13, operation S40 of determining the optimal surface roughness may include providing a test pad conditioner including a test tip (S42), measuring the polishing rate of the chemical mechanical polishing while changing the surface roughness of the upper surface of the test tip (S44), and determining the optimal surface roughness using the measured polishing rate (S46).

The test pad conditioner may be an experimental pad conditioner used to determine the optimal surface roughness. That is, operation S42 of providing a test pad conditioner including a test tip may be similar to operation S10 of providing the pad conditioner 100 including the plurality of tips 120 in FIG. 1.

Operation S44 of measuring the polishing rate of the chemical mechanical polishing while changing the surface roughness of the upper surface of the test tip may include providing a plurality of test pad conditioners and measuring the polishing rate of the chemical mechanical polishing using each of them. Measuring the polishing rate of the chemical mechanical polishing of a plurality of test pad conditioners is described in detail with respect to FIG. 14.

For example, a plurality of test pad conditioners, each including a test tip having an upper surface with a different surface roughness, may be provided. For example, referring to FIG. 14, a first test pad conditioner 100T1, a second test pad conditioner 100T2, and a third test pad conditioner 100T3, each including a test tip having an upper surface with a different surface roughness, may be provided. FIG. 14 illustrates that three test pad conditioners are provided, but the present disclosure is not limited thereto, e.g., three or more test pad conditioners may be provided.

Referring to FIG. 14, providing the first test pad conditioner 100T1, the second test pad conditioner 100T2, and the third test pad conditioner 100T3 may utilize operation S20 in FIG. 1, i.e., adjusting the surface roughness of the upper surface US of each tip 120 in FIG. 1. For example, by adjusting the process conditions of the diamond coating process, a plurality of test pad conditioners, each including a test tip having an upper surface with a different surface roughness, may be provided, e.g., the process conditions of a diamond coating process in the first through third pad conditioners of FIG. 14 may be adjusted to adjust surface roughness of the test tips. In another example, by adjusting the degree of dressing of the test pad conditioner, a plurality of test pad conditioners, each including a test tip having an upper surface with a different surface roughness, may be provided e.g., the degree of dressing of the first through third pad conditioners of FIG. 14 may be adjusted to adjust surface roughness of the test tips.

The measurement of the polishing rate of the chemical mechanical polishing using a plurality of test pad conditioners may be similar to that described with reference to FIGS. 9 to 11. For example, the conditioning process may be performed on the polishing pad 320 using each of the first test pad conditioner 100T1, the second test pad conditioner 100T2, and the third test pad conditioner 100T3. Then, the wafer WF may be polished by using the polishing pad 320 subjected to the conditioning process, e.g., different wafers WF may be polished by using polishing pads 320 subjected to the conditioning process via the first through this test pad conditioners 100T1 through 100T3. Then, the polishing rate of the chemical mechanical polishing using each of the first test pad conditioner 100T1, the second test pad conditioner 100T2, and the third test pad conditioner 100T3 may be measured, e.g., in accordance with different degrees of surface roughness and slurry composition. Thus, the polishing rate of the chemical mechanical polishing may be measured while changing the surface roughness of the upper surface of the test tip.

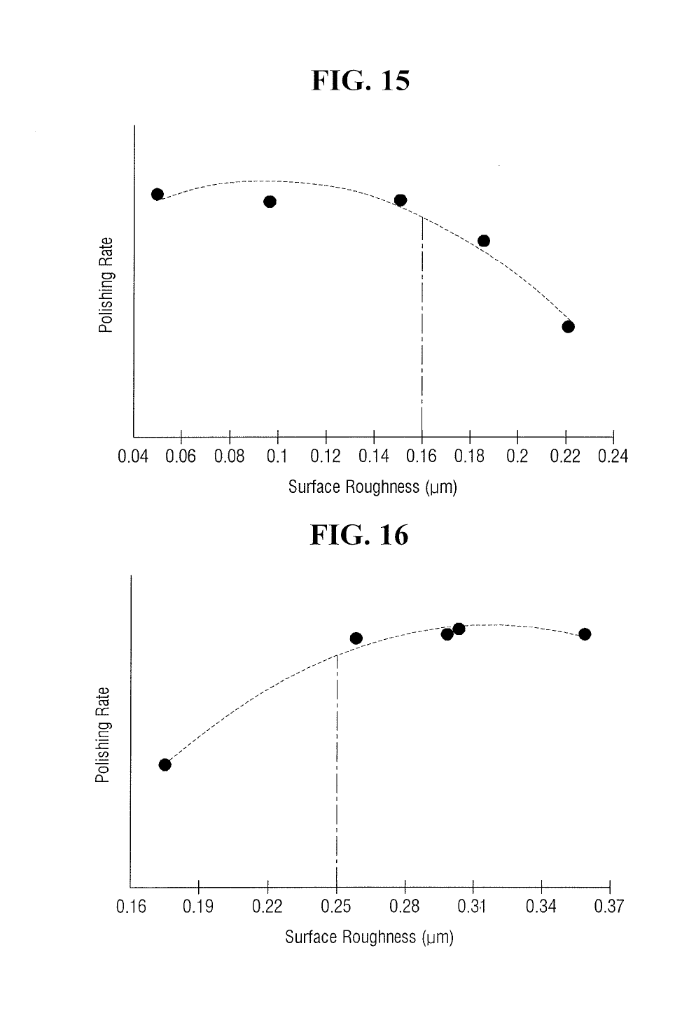

Referring again to FIG. 13, the optimal surface roughness is determined using the measured polishing rate (S46). Here, the optimal surface roughness refers to the surface roughness of the upper surface US of the tip 120 of the pad conditioner 100, which provides the polishing rate required according to the process. For example, the optimal surface roughness may be determined in accordance with measurement results, after testing the first test pad conditioner 100T1, the second test pad conditioner 100T2, and the third test pad conditioner 100T3 with different degrees of surface roughness and slurry composition, e.g., as will be described in more detail with reference to FIGS. 15-16.

FIG. 15 is a graph explaining the determination of the optimal surface roughness using the measured polishing rate in some embodiments of the present disclosure. For reference, FIG. 15 is a graph showing a change in the polishing rate according to the change in the surface roughness of the upper surface US of the tip 120 in the chemical mechanical polishing method using the polishing slurry 520 including a ceria abrasive. In FIG. 15, the surface roughness of the upper surface US of the tip 120 is obtained by measuring a protruding peak height (RPK) among lubricity evaluation parameters of a plateau structure surface.

Referring to FIG. 15, it can be seen that, in the chemical mechanical polishing method according to some embodiments, the polishing rate is improved as the surface roughness of the upper surface US of the tip 120 is reduced. That is, in the chemical mechanical polishing method using the polishing slurry 520 including the ceria abrasive, the reduced surface roughness of the polishing pad 320 can improve the polishing rate. It is understood that this is due to the characteristics of the ceria abrasive polishing the wafer WF. The ceria abrasive may form a Si—O—Ce bond with an oxide film of the wafer WF to remove the oxide of the wafer WF in a lump form. Accordingly, in the chemical mechanical polishing method using a ceria abrasive, the polishing rate tends to increase as the contact area between the polishing pad 320 and the wafer WF increases. That is, in some embodiments, by reducing the surface roughness of the upper surface US of the tip 120, the surface roughness of the polishing pad 320 can be reduced, thereby improving the polishing rate.

In some embodiments, using the graph as in FIG. 15, the surface roughness providing the polishing rate required according to the process may be determined as the optimal surface roughness. For example, when a high polishing rate is required, the surface roughness of about 0.16 μm or less may be determined as the optimal surface roughness.

Further, in the chemical mechanical polishing method according to some embodiments, the surface roughness providing a stable polishing rate may be determined as the optimal surface roughness. As shown in FIG. 15, it can be seen that when the surface roughness of the upper surface US of the tip 120 is below a certain level, a change in the polishing rate is not large. For example, it can be seen that when the surface roughness of the upper surface US of the tip 120 ranges from about 0.04 μm to about 0.16 μm, a change in the polishing rate is not large, e.g., negligible. Accordingly, a surface roughness of about 0.04 μm to about 0.16 μm, e.g., about 0.04 μm to about 0.1 μm, may be determined as the optimal surface roughness.

FIG. 16 is a graph explaining the determination of the optimal surface roughness using the measured polishing rate in some embodiments of the present disclosure. For reference, FIG. 16 is a graph showing a change in the polishing rate according to a change in the surface roughness of the upper surface US of the tip 120 in the chemical mechanical polishing method using the polishing slurry 520 including a silica abrasive (as opposed to a ceria abrasive in FIG. 15). As in FIG. 15, in FIG. 16, the surface roughness of the upper surface US of the tip 120 is obtained by measuring a protruding peak height (RPK) among lubricity evaluation parameters of a plateau structure surface.

Referring to FIG. 16, it can be seen that, in the chemical mechanical polishing method according to some embodiments, the polishing rate is improved as the surface roughness of the upper surface US of the tip 120 is increased. That is, in the chemical mechanical polishing method using the polishing slurry 520 including the silica abrasive, the increased surface roughness of the polishing pad 320 can improve the polishing rate. It is understood that this is due to the characteristics of the silica abrasive polishing the wafer WF. The polishing slurry 520 containing the silica abrasive may dissolve the oxide of the wafer by a hydration reaction. Thus, in the chemical mechanical polishing method using the silica abrasive, the polishing rate tends to increase as the polishing pad 320 has a rough surface and the slurry can flow more easily. That is, in some embodiments, by increasing the surface roughness of the upper surface US of the tip 120, the surface roughness of the polishing pad 320 can be increased, thereby improving the polishing rate.

In some embodiments, using the graph as in FIG. 16, the surface roughness providing the polishing rate required according to the process may be determined as the optimal surface roughness. For example, when a high polishing rate is required, the surface roughness of about 0.25 μm or more may be determined as the optimal surface roughness.

Further, in the chemical mechanical polishing method according to some embodiments, the surface roughness providing a stable polishing rate may be determined as the optimal surface roughness. As shown in FIG. 16, it can be seen that when the surface roughness of the upper surface US of the tip 120 is above a certain level, a change in the polishing rate is not large. For example, it can be seen that when the surface roughness of the upper surface US of the tip 120 is about 0.25 μm or more, a change in the polishing rate is not large, e.g., negligible. Accordingly, the surface roughness of about 0.25 μm or more, e.g., about 0.25 μm to about 0.5 μm, may be determined as the optimal surface roughness.

Referring again to FIG. 12, once the optimal surface roughness is determined (S40) in accordance with the test pad conditioner, e.g., via experimentation results as in FIGS. 15-16, the surface roughness of the upper surface US of the tip 120 of the pad conditioner 100 is adjusted (S22′) in accordance with the results determined in operation (S40). Adjusting the surface roughness of the upper surface US of the tip 120 of the pad conditioner 100 may include forming a plurality of tips 120 such that the upper surface US of the tip 120 has the determined optimal surface roughness, e.g., as determined in accordance with the multiple tips tested in operations S42 through S46 in FIG. 13.

Forming the plurality of tips 120 to have the determined optimal surface roughness may be performed in accordance with operation S20 in FIG. 1, i.e., adjusting the surface roughness of the upper surface US of each tip 120 in FIG. 1. For example, the process conditions of the diamond coating process may be adjusted to form the plurality of tips 120 to have the determined optimal surface roughness. In another example, by adjusting the degree of dressing of the test pad conditioner, the plurality of tips 120 may be formed to have the determined optimal surface roughness.

For example, adjusting the surface roughness of the upper surface US of the tip 120 of the pad conditioner 100 may include forming the plurality of tips 120 such that the surface roughness of the upper surface US of the tip 120 rages from about 0.01 μm to about 0.16 μm. In another example, adjusting the surface roughness of the upper surface US of the tip 120 of the pad conditioner 100 may include forming the plurality of tips 120 such that the surface roughness of the upper surface US of the tip 120 rages from about 0.25 μm to about 0.5 μm, e.g., about 0.3 μm to about 0.5 μm.

Then, a conditioning process is performed on the polishing pad 320 using the pad conditioner 100 (S32′). According to some embodiments, the pad conditioner 100 including the plurality of tips 120 having an optimal surface roughness can form, e.g., adjust, the surface roughness of the polishing pad 320 required according to the process. In addition, according to some embodiments, the pad conditioner 100 including the plurality of tips 120 having an optimal surface roughness can form, e.g., adjust, the surface roughness of the polishing pad 320 to realize a stable polishing rate, e.g., regardless of the use time.

Then, the wafer WF is polished using the polishing pad 320 (S34′). The polishing pad 320 having the surface roughness required according to the process can provide the polishing rate of the chemical mechanical polishing required according to the process. Accordingly, the chemical mechanical polishing method according to some embodiments can realize an optimized polishing rate for each process, e.g., in accordance with slurry type. In addition, the chemical mechanical polishing method according to some embodiments can realize a stable polishing rate, e.g., in accordance with an optimal surface roughness as determined by the test tips.

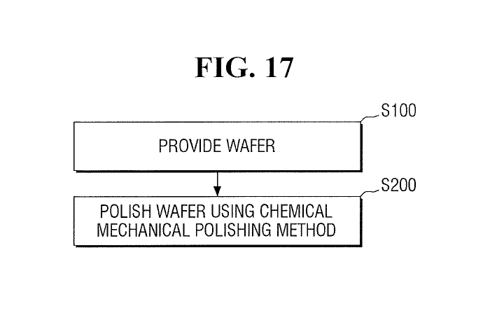

FIG. 17 is a flowchart explaining a method for fabricating a semiconductor device according to some embodiments of the present disclosure. For convenience of description, a repeated description similar to the description with reference to FIGS. 1 to 16 will be only briefly explained or omitted.

Referring to FIG. 17, the wafer WF is provided (S100). As described above with reference to FIG. 11, the wafer WF may be provided onto the polishing pad 320.

Then, the wafer is polished using the chemical mechanical polishing method according to some embodiments (S200). For example, the pad conditioner 100 including the plurality of tips 120 may be provided (S10 of FIG. 1). Then, the surface roughness of the upper surface US of each tip 120 may be adjusted (S20 in FIG. 1). Then, the polishing rate of the chemical mechanical polishing may be adjusted (S30 in FIG. 1). Operation S30 of adjusting the polishing rate of the chemical mechanical polishing may include performing a conditioning process on the polishing pad 320 using the pad conditioner 100 (S32 in FIG. 9) and polishing the wafer WF using the polishing pad 320 (S34 in FIG. 9).

Thus, it is possible to provide a method for fabricating a semiconductor device, which realizes an optimized polishing rate for each process. In addition, it is possible to provide a method for fabricating a semiconductor device, which realizes a stable polishing rate.

By way of summation and review, in a continuous wafer planarization process, a polishing pad of a CMP apparatus may be damaged by slurry or foreign matter. As a result, the profile of the polishing pad may be altered to a state different from its initial state, which deteriorates the stability of the wafer planarization process. Accordingly, in order to continuously carry out the wafer planarization process by using the CMP apparatus, various kinds of pad conditioners capable of stably maintaining the profile of the polishing pad and a chemical mechanical polishing method using a pad conditioner are required.

Therefore, aspects of embodiments provide a method for fabricating a semiconductor device using a chemical mechanical polishing method capable of realizing an optimized polishing rate for each process. Aspects of embodiments also provide a chemical mechanical polishing method capable of realizing an optimized polishing rate for each process by adjusting the surface roughness of a pad conditioner.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A chemical mechanical polishing method, the method comprising:
providing a pad conditioner, such that the pad conditioner includes a base and a plurality of tips protruding from a surface of the base;
adjusting a surface roughness of an upper surface of each tip of the plurality of tips; and
adjusting a polishing rate of chemical mechanical polishing using the adjusted surface roughness of the upper surfaces of the plurality of tips.

2. The chemical mechanical polishing method as claimed in claim 1, wherein adjusting the polishing rate of chemical mechanical polishing includes:
adjusting a surface roughness of a polishing pad using the adjusted surface roughness of the upper surfaces of the plurality of tips of the pad conditioner; and
using the adjusted surface roughness of the polishing pad to perform chemical mechanical polishing on a surface of a wafer.

3. The chemical mechanical polishing method as claimed in claim 1, wherein each tip of the plurality of tips includes:
a protrusion protruding from the surface of the base; and
a cutting portion covering an upper surface of the base, a sidewall of the protrusion, and an upper surface of the protrusion.

4. The chemical mechanical polishing method as claimed in claim 3, wherein the cutting portion includes chemical vapor deposition (CVD) diamond.

5. The chemical mechanical polishing method as claimed in claim 1, wherein providing the pad conditioner and adjusting the surface roughness of the upper surface of each tip of the plurality of tips are performed simultaneously.

6. The chemical mechanical polishing method as claimed in claim 5, wherein:
providing the pad conditioner includes performing a diamond coating process, and
adjusting the surface roughness of the upper surface of each tip of the plurality of tips includes adjusting process conditions of the diamond coating process.

7. The chemical mechanical polishing method as claimed in claim 1, wherein adjusting the surface roughness of the upper surface of each tip of the plurality of tips includes reducing the surface roughness of the upper surface of each tip of the plurality of tips.

8. The chemical mechanical polishing method as claimed in claim 7, wherein reducing the surface roughness of the upper surface of each tip of the plurality of tips includes performing dressing on the upper surface of each tip of the plurality of tips.

9. The chemical mechanical polishing method as claimed in claim 1, wherein each tip of the plurality of tips has a shape of a truncated pyramid, a truncated cone, a prism, or a cylinder.

10. The chemical mechanical polishing method as claimed in claim 9, wherein a width of the upper surface of each tip of the plurality of tips ranges from 10 μm to 100 μm.

11. The chemical mechanical polishing method as claimed in claim 9, wherein a height of each tip of the plurality of tips ranges from 30 μm to 250 μm.

12. A chemical mechanical polishing method, the method comprising:
providing a pad conditioner, such that the pad conditioner includes a base and a plurality of tips protruding from a surface of the base;
determining an optimal surface roughness of an upper surface of each tip of the plurality of tips;
adjusting a surface roughness of the upper surface of each tip of the plurality of tips, such that the upper surface of each tip of the plurality of tips has the optimal surface roughness;
performing conditioning on a polishing pad using the pad conditioner; and
polishing a wafer using the polishing pad.

13. The chemical mechanical polishing method as claimed in claim 12, wherein determining the optimal surface roughness of the upper surface of each tip of the plurality of tips is performed before providing the pad conditioner.

14. The chemical mechanical polishing method as claimed in claim 13, wherein determining the optimal surface roughness includes:
providing a test pad conditioner including a test tip;
measuring a polishing rate of chemical mechanical polishing while changing a surface roughness of an upper surface of the test tip; and
determining the optimal surface roughness using the measured polishing rate.

15. The chemical mechanical polishing method as claimed in claim 12, wherein:
the optimal surface roughness ranges from 0.04 μm to 0.16 μm, and
polishing the wafer includes performing polishing using a slurry containing a ceria abrasive and the polishing pad.

16. The chemical mechanical polishing method as claimed in claim 12, wherein:
the optimal surface roughness ranges from 0.25 μm to 0.5 μm, and polishing the wafer includes performing polishing using a slurry containing a silica abrasive and the polishing pad.

17. The chemical mechanical polishing method as claimed in claim 12, wherein providing the pad conditioner includes:
providing the base and a protrusion protruding from the surface of the base; and
performing a diamond coating process on the base and the protrusion to form a cutting portion.

18. The chemical mechanical polishing method as claimed in claim 17, wherein adjusting the surface roughness of the upper surface of each tip of the plurality of tips includes adjusting process conditions of the diamond coating process.

19. The chemical mechanical polishing method as claimed in claim 12, wherein the surface roughness of each tip of the plurality of tips includes performing dressing on the upper surface of each tip of the plurality of tips.

20. A method for fabricating a semiconductor device, the method comprising:
providing a wafer; and
polishing the wafer using a chemical mechanical polishing method, the chemical mechanical polishing method including:
providing a pad conditioner, such that the pad conditioner includes a base and a plurality of tips protruding from a surface of the base,
adjusting a surface roughness of an upper surface of each tip of the plurality of tips, and
adjusting a polishing rate of chemical mechanical polishing using the adjusted surface roughness of the upper surfaces of the plurality of tips.
